(19) United States
(12) Patent Application Publication
(10) Pub. No.: US 2014/0300386 A1
(43) Pub. Date: Oct. 9, 2014

(54) VOLTAGE LEVEL SHIFTER CIRCUIT, SYSTEM, AND METHOD FOR HIGH SPEED APPLICATIONS

(71) Applicant: STMICROELECTRONICS INTERNATIONAL N.V., AMSTERDAM (NL)

(72) Inventors: Nitin JAIN, GHAZIABAD (IN); Nitin GUPTA, KURUKSHETRA (IN)

(73) Assignee: STMICROELECTRONICS INTERNATIONAL N.V., AMSTERDAM (NL)

(21) Appl. No.: 14/231,026

(22) Filed: Mar. 31, 2014

Related U.S. Application Data
(60) Provisional application No. 61/806,501, filed on Mar. 29, 2013.

(51) Int. Cl. H03K 19/0175

(52) U.S. Cl. CPC H03K 19/017509
USPC 326/81

(57) ABSTRACT

A level shifting circuit includes a first inverter including a pair of transistors of opposite conductivity type, the first inverter adapted to receive an input signal in a first voltage domain and further including at least one additional transistor driven by a voltage in a second voltage domain. A second inverter is coupled in series with the first inverter and operable to generate an output signal in the second voltage domain. The second inverter includes a pair of transistors of opposite conductivity type, and further includes at least one additional transistor driven by a voltage in the first voltage domain. The additional transistors are operable to approximately equalize the fall times of output signals generated by the first and second inverters.

### PRIORITY CLAIM

The present application claims priority to U.S. Provisional Patent Application No. 61/806,501, filed Mar. 29, 2013, which application is incorporated herein by reference in its entirety.

### TECHNICAL FIELD

The present disclosure relates generally to level shifting circuits and more specifically to level shifting circuits for shifting the voltage levels of high speed signals from one voltage domain to another with minimum or reduced duty cycle distortion of the signal.

### BACKGROUND

In current high frequency (i.e., gigahertz plus) chips or integrated circuits, to optimize power consumption and high speed operation performance of the integrated circuit selective circuits in the integrated circuit are switched OFF or a supply voltage VDD supplied to such circuits is reduced or increased depending on the need for low power or high speed operation at that time. Moreover, within a given integrated circuit, such as in a system on a chip (SoC) application, there are multiple supply voltage levels or “voltage domains” and signals, such as a clocking or clock signal, must propagate across these different voltage domains during operation of the integrated circuit. The terms voltage domain, supply voltage domain, and supply voltage level will be used interchangeably in the present description. As a result, level shifters or level shifting circuits that function to convert signals in one voltage domain to signals in another voltage domain must be utilized. This level shifting of signals presents challenges, particularly at high frequencies, since distortion of the clock or other signal propagating form one voltage domain to another may result in significant distortion of the signal being introduced by the level shifter. Where the propagating signal is a clock signal, for example, significant distortion of the duty of the clock signal may be introduced by level shifters at these high frequencies. There is therefore a need for new techniques for propagating clock or other signals between and among multiple voltage domains without distorting the duty cycle of the signal.

### SUMMARY

A level shifting circuit includes a first inverter including a pair of transistors of opposite conductivity type, the first inverter adapted to receive an input signal in a first voltage domain and further including at least one additional transistor driven by a voltage in a second voltage domain. A second inverter is coupled in series with the first inverter and operable to generate an output signal in the second voltage domain. The second inverter includes a pair of transistors of opposite conductivity type, and further includes at least one additional transistor driven by a voltage in the first voltage domain. The additional transistors are operable to approximately equalize the fall times of output signals generated by the first and second inverters.

### BRIEF DESCRIPTION OF THE DRAWINGS

FIG. 1 is a schematic of a level shifting circuit that may introduce significant distortion in the duty cycle of an output clock signal relative to an input clock signal during high frequency operation.

FIG. 2 is a signal timing diagram illustrating various signals generated during the operation of the level shifting circuit of FIG. 1 and showing the resulting duty cycle distortion in the generated output clock signal.

FIG. 3 is a schematic of a high speed level shifting circuit according to one embodiment of the present disclosure.

FIG. 4 is a schematic of a high speed level shifting circuit according to another embodiment of the present disclosure.

FIG. 5 is schematic of one embodiment of the output buffer portion of the level shifting circuits of FIGS. 3 and 4.

FIG. 6 is a functional block diagram of an electronic system including one more of the level shifting circuits of FIGS. 3 and 4 according to another embodiment of the present disclosure.

### DETAILED DESCRIPTION

Level shifters or level shifting circuits according to embodiments of the present disclosure compensate for the effect that differing voltages from different voltage domains applied to complementary metal oxide semiconductor (CMOS) devices forming the level shifting circuit have on the high frequency operation of the level shifting circuit, as will be described in more detail below. In the following description, certain details are set forth in conjunction with the described embodiments of the present disclosure to provide a sufficient understanding of the disclosure. One skilled in the art will appreciate, however, that embodiments of the disclosure may be practiced without these particular details. Furthermore, one skilled in the art will appreciate that the example embodiments described below do not limit the scope of the present disclosure, and will also understand that various modifications, equivalents, and combinations of the disclosed embodiments and components of such embodiments are within the scope of the present disclosure. Embodiments including fewer than all the components of any of the respective described embodiments may also be within the scope of the present disclosure although not expressly described in detail below. Finally, the operation of well-known components and/or processes has not been shown or described in detail below to avoid unnecessarily obscuring the present disclosure.

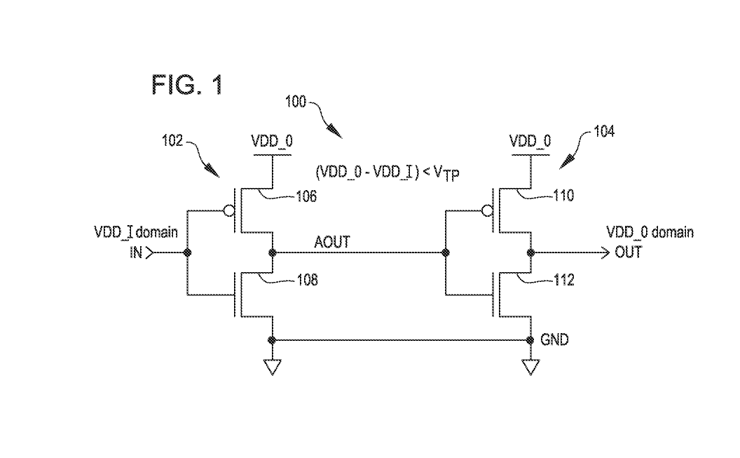

FIG. 1 is a schematic of a level shifting circuit 100 that may introduce significant distortion in the duty cycle of an output clock signal OUT relative to an input clock signal IN during high frequency operation. The input clock signal IN is in a first voltage domain defined by a supply voltage VDD_I and a reference voltage GND while the output clock signal OUT is in a second voltage domain defined by a supply voltage VDD_O and the reference voltage GND. The level shifting circuit 100 is formed by two inverter 102 and 104 connected in series, with the first inverter 102 including a PMOS transistor 106 and NMOS transistor 108 coupled in series between the supply voltage VDD_O and ground (i.e., reference voltage GND) and the second inverter 104 including a PMOS transistor 110 and NMOS transistor 112 coupled in series between the supply voltage VDD_O and ground. The first inverter 102 generates a first intermediate output signal AOUT in response to the input signal IN and the inverter 104 generates the OUT signal in response to the AOUT signal. In the present description, the VDD_I voltage associated with the voltage domain of the IN signal is assumed to be less than the VDD_O voltage associated with the voltage domain of the OUT signal. The VDD_I voltage is, however, assumed to be less than the VDD_O voltage by less than one threshold voltage VTP of each of the PMOS transistors 106 and 110. In this way, when the IN signal is high (i.e., at voltage VDD_I), the PMOS transistor 106 is turned OFF. The reference voltage GND may also be referred to simply as “ground” herein.

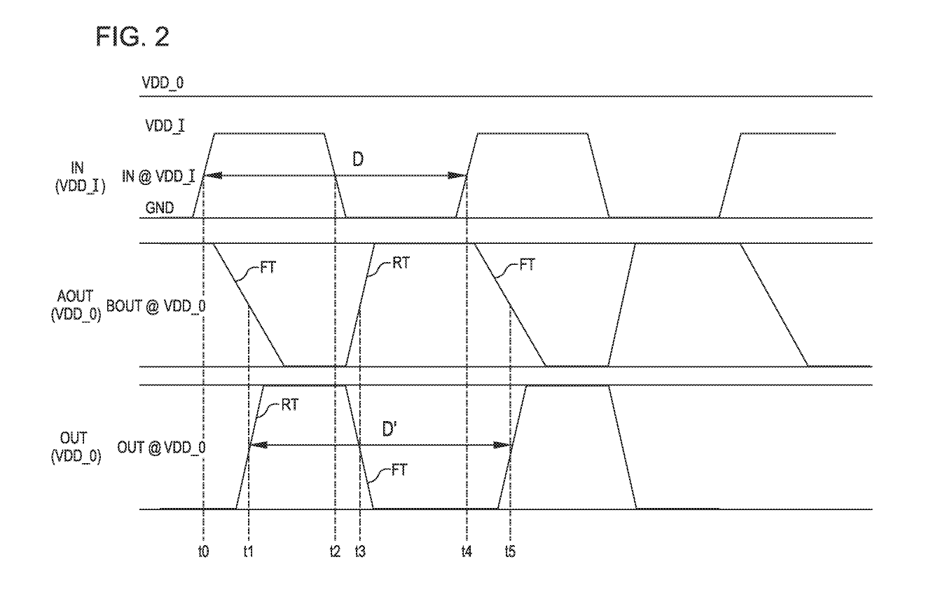

FIG. 2 is a signal timing diagram illustrating various signals generated during the operation of the level shifting circuit 100 of FIG. 1 and showing the distortion of the duty cycle D′ of the OUT signal relative to the duty cycle D of the IN signal. At high frequencies of the IN signal, picosecond differences between the duty cycle D′ and the duty cycle D can be significant in terms of percentage difference and can thus adversely affect the operation of circuitry utilizing the OUT signal. For example, a 4 GHz signal has a 250 ps period and thus a 25 ps variation between the duty cycle D′ of the OUT signal and the duty cycle D of the IN signal can adversely affect the operation of circuitry utilizing the OUT signal. Referring now to the signal timing diagram of FIG. 2, signals IN, AOUT and OUT are illustrated.

The detailed operation of the level shifting circuit 100 will now be described with reference to FIG. 2. At a time t0, the IN signal goes high to the voltage VDD_I, turning OFF the PMOS transistor 106 and turning ON the NMOS transistor 108 in the first inverter 102. The NMOS transistor 108 is activated by the IN signal at the voltage VDD_I, and thus the gate-to-source voltage VGS of this NMOS transistor is VDD_I and activates the NMOS transistor to drive the AOUT signal low, which is seen a time t1. In response to the NMOS transistor 108 driving the AOUT signal low, the PMOS transistor 110 in the second inverter 104 turns ON to thereby drive the OUT signal high, which is seen as occurring just after the time t1. Notice the PMOS transistor 110 receives a gate-to-source voltage of VDD_O as the AOUT signal goes low to ground GND. Thus, when the IN signal goes high the NMOS transistor 108 turns ON with the voltage VGS of the voltage VDD_I and the PMOS transistor 110 turns ON with the voltage VGS of the voltage VDD_O. Since the supply voltage VDD_I is less than the supply voltage VDD_O, the voltage VGS driving the NMOS transistor 108 is lower which results in the NMOS transistor driving the AOUT signal more slowly. This is seen in FIG. 2 in the form of the falling edge of the AOUT signal centered on the time t1 takes longer than the rising edge of the OUT signal occurring just after this time. This falling edge of the AOUT signal is indicated as having a fall time FT.

At a time t2, the IN signal goes low to the reference voltage GND, turning OFF the NMOS transistor 108 and turning ON the PMOS transistor 106 in the first inverter 102. The PMOS transistor 106 is activated by the IN signal at the ground voltage GND and thus the gate-to-source voltage VGS of this PMOS transistor is VDD_O. The activated PMOS transistor 106 drives the AOUT signal high, which is seen occurring a time t3. Due to the increased drive of the PMOS transistor 106, namely VGS=VDD_O, the rising edge of the AOUT signal has a rise time RT that is less than the fall time FT of this signal, as seen in FIG. 2. In response to the PMOS transistor 106 driving the AOUT signal high, in the second inverter 104 the PMOS transistor 110 turns OFF and the NMOS transistor turns ON to thereby drive the OUT signal low, which is seen occurring just after the time t3. The PMOS transistor 112 in the second inverter 104 receives a voltage VGS of VDD_O as the AOUT signal goes high to the supply voltage VDD_O. Rise times RT and fall times FT of the OUT signal are indicated in FIG. 2 as well, and notice each of these is approximately the same while the fall time FT of the AOUT signal is longer as discussed above. At a time t4 the IN signal again goes high, turning ON the NMOS transistor 108 with the voltage VGS of VDD_I to drive the AOUT signal low as previously described, and the same is true for the PMOS transistor 110 turning ON at approximately a time t5 responsive to the low AOUT signal (VGS for PMOS transistor 110 of VDD_O) and driving the OUT signal high just after the time t5 as seen in FIG. 2. This completes the operation of the level shifting circuit 100 during one cycle of period of the IN signal.

As seen from the above operation, each of the MOS transistors 106, 110 and 112 in the first and second inverters 102 and 104 receives a gate-to-source voltage VGS of VDD_O when that transistor is turned ON or activated. In contrast, however, the NMOS transistor 108 receives the gate-to-source voltage VGS of VDD_I. This results in asymmetrical operation of the level shifting circuit 100, which changes or distorts the duty cycle D′ of the OUT signal relative to the duty cycle D of the IN signal. The operation is asymmetrical in that the fall time FT of the AOUT signal is longer due to the NMOS transistor 108 receiving VGS=VDD_I. This longer fall time FT of the AOUT signal delays the corresponding rising edge of the OUT signal and thereby changes or distorts the duty cycle D′ of the OUT signal. Only the NMOS transistor 108 receives this VGS=VDD_I when the IN signals goes high (i.e., from GND to VDD_I). This lower magnitude VGS applied to the NMOS transistor 108 causes the fall time FT of the AOUT signal to be longer than the rise time of the AOUT signal and it is this difference between the rise and fall times RT, FT of the AOUT signal, along with the rise and fall times RT, FT of the second inverter 104 being the same, which causes an unwanted change in the duty cycle D′ of the OUT signal relative to the duty cycle D of the input signal IN as shown in FIG. 2.

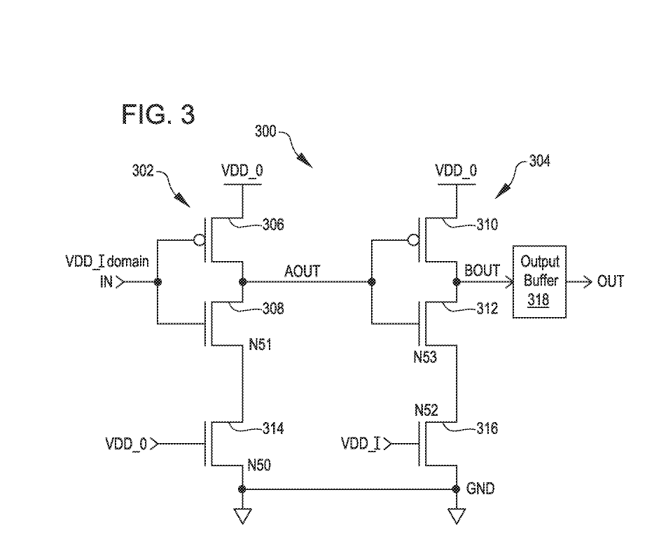

FIG. 3 is a schematic of a high speed level shifting circuit 300 according to one embodiment of the present disclosure. The high-speed level shifting circuit 300 includes components 302-312 that correspond to the components 102-112 previously described with reference to the level shifting circuit 100 of FIG. 1 and thus these components will not again be described in detail with reference to FIG. 3. In the embodiment of FIG. 3, each of the first inverter 302 and the second inverter 304 includes an additional NMOS transistor. More specifically, the first inverter 302 includes the NMOS transistor 314 coupled between the NMOS transistor 308 and ground and receiving the supply voltage VDD_O on its gate. Similarly, the second inverter 304 includes the NMOS transistor 316 coupled between the NMOS transistor 312 and ground and receiving the supply voltage VDD_I on its gate.

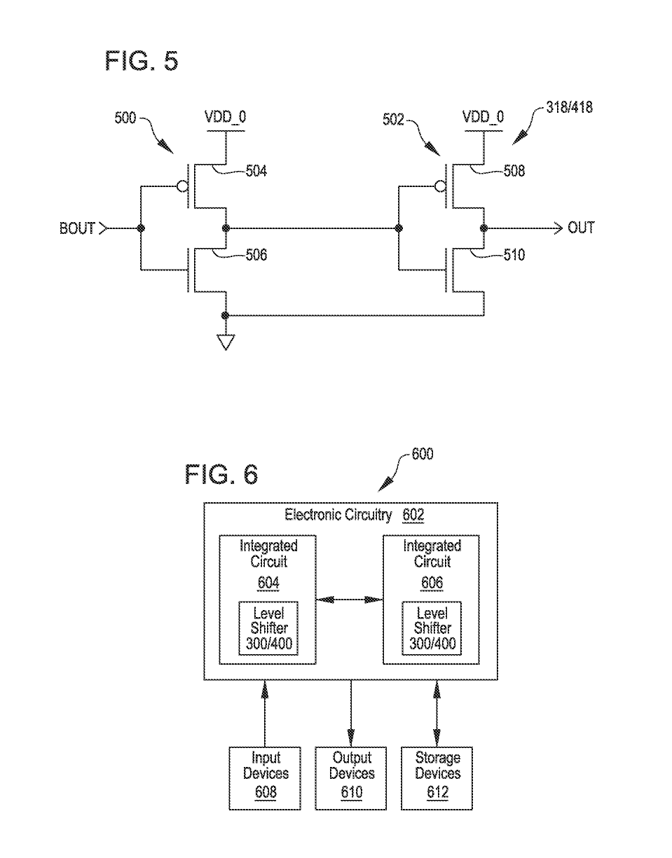

The inclusion of the additional NMOS transistors 314 and 316 in the first and second inverters 302 and 304, respectively, balances or equalizes the rise times RT and fall times FT of these inverters so that the inverters are symmetrical. More specifically, the inverters 302 and 304 are symmetrical in that the fall times FT of the inverters are the same, which is contrary to the inverters 102 and 104 of FIG. 1. In operation, when the IN signal goes high (i.e., to VDD_I), the PMOS transistor 306 turns OFF and the NMOS transistor 308 turns ON just as for the operation of the circuit 100 of FIG. 1. In response to the AOUT signal going low, the PMOS transistor 310 in the second inverter 304 once again receives a voltage VGS=VDD_O and drives a second intermediate output signal BOUT high. An output buffer 318 receives the BOUT signal and drives a final output signal OUT to the same level as that of the BOUT signal, where the output buffer functions to provide the required power to adequately drive the OUT signal, as will be described in more detail below with reference to FIG. 5.

When the IN signal goes low to the voltage GND, the NMOS transistor 308 turns OFF and the PMOS transistor 306 is driven with a voltage VGS=VDD_O and thereby drives the first intermediate output signal AOUT high. In response to the AOUT signal going high, the PMOS transistor 310 in the second inverter 304 turns OFF and the NMOS transistor 312 turns ON. At this point, the series connected NMOS transistors 312 and 316 drive the second intermediate output signal BOUT low. The drive strengths of these two NMOS transistors 312 and 316 in the second inverter 304 are collectively the same as those for the NMOS transistors 308 and 314 in the first inverter 302. The NMOS transistor 312 is driven with a voltage VGS=VDD_O since the AOUT signal is high at voltage VDD_O but the additional NMOS transistor 316 is driven with a voltage VGS=VDD_I. As a result, the fall time FT of the BOUT signal depends on the drive strengths of the two NMOS transistors 312 and 316 and once again because these NMOS transistors are connected in series the overall drive strength that determines the fall time of the BOUT signal is determined by the smaller of these two drive strengths, namely the voltage VGS=VDD_I applied to the additional NMOS transistor 316. Thus, the second inverter 304 has a fall time FT determined by the drive strength of the additional NMOS transistor 316 (VGS=VDD_I) and this is the same drive strength and fall time for the first inverter 302 as determined by the NMOS transistor 308.

In sum, with the level shifting circuit 300 at certain frequency ranges the fall times FT for both the first inverter 302 and second inverter 304 are approximately the same, meaning that the duty cycle D of the second intermediate output signal BOUT is approximately the same as that of the input signal IN. The output buffer 318 operates in the second voltage domain (VDD_O to GND) and does not distort the duty cycle of the BOUT signal such that the OUT signal has approximately the same duty cycle as the BOUT signal and thereby the same duty cycle as the IN signal. When the frequency of the IN signal is high enough, however, even the level shifting circuit 300 may unacceptably distort the duty cycle of the OUT signal due to differences in the duty cycles of the AOUT and BOUT signals that result from differences in the fall times FT of the first and second inverter 302 and 304. This may occur because the source of the NMOS transistor 308 in the first inverter 302, the gate of which is driven by the voltage VDD_I when this transistor N is turned ON, is referenced to the drain of the NMOS transistor 314 but the source of the corresponding NMOS transistor 316 in the second inverter 304, the gate of which is also driven by voltage VDD_I, is referenced to the voltage GND. As a result, due to body effect of a MOS transistor, for example, the conduction of the NMOS transistors 308 and 316 may be slightly different, causing differences in the fall times of the two inverters 302 and 304 and thereby introducing duty cycle distortion of the BOUT signal and thus the OUT signal. Another reason for slight asymmetrical fall time operation of the inverters 302 and 304 is that in the first inverter 302 the source of the NMOS transistor 314 that is driven by VDD_0 on its gate and the source of this transistor is coupled to the ground voltage GND, where in the second inverter 304 the source of the NMOS transistor 312 that is also driven by VDD_0 and the source of this transistor is coupled to the drain of the NMOS transistor 316 and not to ground GND. The conduction of the NMOS transistors 314 and 312 may therefore differ slightly, once again due to body effect for example, causing differences in the fall times of the inverters 302 and 304 and thereby causing distortion of the duty cycle of the OUT signal relative to the IN signal.

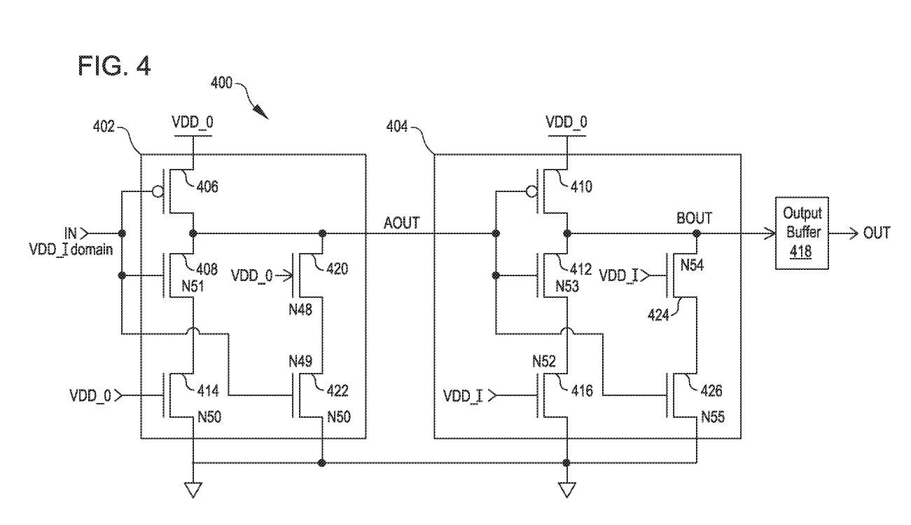

FIG. 4 is a schematic of a high speed level shifting circuit 400 according to another embodiment of the present disclosure. The high-speed level shifting circuit 400 includes components 402-418 that correspond to the components 302-318 previously described with reference to the level shifting circuit 300 of FIG. 3 and thus these components will not again be described in detail with reference to FIG. 4. In the embodiment of FIG. 4, each of the first inverter 402 and the second inverter 404 includes an additional pair of NMOS transistors coupled in series between the output of the inverter and ground. More specifically, the first inverter 402 includes the NMOS transistors 420 and 422 coupled in series between the output of the first inverter 402 at which the AOUT signal is generated and ground GND. The NMOS transistor 420 receives the supply voltage VDD_O on its gate and the NMOS transistor 422 receives the IN signal, which is in the first voltage domain (VDD_I to GND), on its gate. The second inverter 404 includes the NMOS transistors 424 and 426 coupled in series between the output of the second inverter 404 at which the BOUT signal is generated and ground GND. The NMOS transistor 424 receives the supply voltage VDD_I (first voltage domain) on its gate and the NMOS transistor 426 receives the AOUT signal (second voltage domain) on its gate.

In operation, when the input signal IN transitions high to the voltage VDD_I, the fall time FT of the AOUT signal depends on the drive strengths of the four NMOS transistors 408, 414, 420 and 422. The NMOS transistor 414 has a drive strength (i.e., VGS=VDD_O) determined by supply voltage VDD_0 and also has its source coupled to ground GND. The NMOS transistor 408 is driven by voltage VDD_I and has its source coupled to the drain of NMOS transistor 414 that is driven by voltage VDD_0.

Still in the first inverter 402, the NMOS transistor 422 is driven by the voltage VDD_I on its gate (i.e., IN signal is at VDD_I when these NMOS transistors are turned ON) and the source of this NMOS transistor is coupled to ground GND. Finally, the NMOS transistor 420 is driven by the voltage VDD_0 on its gate and its source is coupled to the drain of the PMOS transistor 422 that is driven by voltage VDD_I.

Furthermore, when the input signal IN transitions low to ground GND causing the AOUT signal to be driven high through PMOS transistor 406, the fall time FT of the BOUT signal generated by the second inverter 404 depends on the same four drive strengths of the NMOS transistors 412, 416, 424 and 426. More specifically, the NMOS transistor 426 is driven by voltage VDD_0 on its gate in the form of the high AOUT signal, and the source of this transistor is at ground GND. The NMOS transistor 424 is driven by the voltage VDD_I on its gate and has its source coupled to the drain of the NMOS transistor 426 that is driven by voltage VDD_0 at its gate. The NMOS transistor 416 is driven by voltage VDD_I on its gate and has its source coupled to ground GND while the NMOS transistor 412 is driven by voltage VDD_0 through the high AOUT signal and has its source coupled to the drain of the PMOS transistor 416 that is driven by voltage VDD_I on its gate.

In the level shifting circuit 400, the drive strengths of the NMOS transistors 408, 414, 420, 422 that determine the fall time of the AOUT signal are approximately the same as the drive strengths of the NMOS transistors 412, 416, 424, 426 that determine the fall time of the BOUT signal. Each NMOS transistor 408, 414, 420, 422 has a corresponding NMOS transistor 412, 416, 424, 426 that is identically coupled as far as gate or drive voltage applied to the transistor and the coupling of the source of the transistor. In this way, variations that may result from different source coupling, such as body effect, are eliminated. In one embodiment, the level shifting circuit 400 had a difference of only about 20 picoseconds (ps) between the fall times FT of the AOUT and BOUT signals. In this way, when the IN signal has a frequency of 1 GHz, the duty cycle variation between BOUT (and OUT) is only about 2%, which is suitable for many applications.

FIG. 5 is schematic of one embodiment of the output buffer 318/418 of the level shifting circuits of FIGS. 3 and 4. In this embodiment, the output buffer 318/418 includes series connected inverters 500 and 502 including series connected PMOS transistor 504 and NMOS transistor 506 and PMOS transistor 508 and NMOS transistor 510, respectively. The operation of the output buffer 318/418 is the same as that previously described with reference to the circuit 100 of FIG. 1 except that there is no level shifting taking place with output buffer 318/418. The input signal to the output buffer 318/418 is the BOUT signal in the second voltage domain (VDD_0 to GND) and the generated output signal OUT is also in the second voltage domain. As previously mentioned, the transistors 504-510 are sized so that the output buffer 318/418 supplies the necessary power to adequately drive the OUT signal.

The above described embodiments of the level shifting circuits 300 and 400 assume that the reference voltage GND is at the same voltage in both the first or input voltage domain (VDD_I to GND) and the second or output voltage domain (VDD_0 to GND). If the ground voltages of these two domains are not the same but one reference voltage GND1 is not greater than the other reference voltage GND2 by more than the threshold voltage VT of the transistors used in the level shifting circuits 300, 400, then a circuit dual of either of the above described embodiments may be used with the PMOS transistors of the first and second inverters to force the rise time of the intermediate signal AOUT to be approximately equal to the rise time of the BOUT signal. Furthermore, if supply voltage VDD_I=VDD_0 but ground voltages GND1 and GND2 of the two voltage domains are different, then the first and second inverters in the circuits 300/400 may include the above described PMOS transistors dual circuitry (two or four PMOS transistors) and only a single NMOS transistor 408 and 412. The above described embodiments may also be combined, such by using the four NMOS transistors per inverter topology of the embodiment of FIG. 4 with the two NMOS transistors per inverter topology of the embodiment of FIG. 3, or the other variations just described.

Still other embodiments of the present disclosure are directed to level shifting circuits in the input supply voltage VDD_I is more than one threshold voltage VTP (i.e., (VDD_O−VDD_I)>VTP. The same concepts discussed above with reference to the embodiments of FIGS. 3 and 4 may be applied to level shifting circuits where the magnitude of (VDD_O−VDD_I) is greater than the threshold voltages of the MOS devices in the circuit, such as the PMOS transistors. Moreover, other embodiments are directed to level shifting circuits where two different reference voltages other than ground GND are utilized, such as where the IN signal varies between VDD_I and a first reference voltage VREF1 and the OUT signal varies between VDD_O and a second reference voltage VREF2. In this situation the level shifting circuit may be an up level shifting circuit where (VDD_O>VDD_I) or a down level shifting circuit where (VDD_O<VDD_I). The concepts discussed with reference to the embodiments of FIGS. 3 and 4 above may be applied to these types of level shifting circuits as well. Also note that other embodiments may utilize different types of technologies, such as bipolar transistors. Also note that the NMOS and PMOS transistors described above may be referred to as transistors having a certain conductivity type, where, for example, the NMOS transistors could be referred to as transistors having a first conductivity type and PMOS transistors as transistors having a second or opposite conductivity type, or vice versa.

FIG. 6 is a functional block diagram of an electronic system 600 including electronic circuitry 602 that contains one more integrated circuits 604, 606, with some or all of these integrated circuits including one or more of the level shifting circuits or level shifters 300 and 400 of FIGS. 3 and 4 according to another embodiment of the present disclosure. The electronic 602 performs desired functions, such as executing specific software or operating to perform a specific function. The electronic system 600 may be a computer system, such as a personal, laptop, or tablet computer, or could be an electronic device such as a smart phone. Where the electronic system 600 is a smart phone, for example, the electronic circuitry 602 would include the mobile processor and chip set for that processor. The electronic system 600 further includes one or more input devices 608, such as a keyboard, mouse, keypad, touch screen, and so on, which is coupled to the electronic circuitry 602. Typically, the electronic system 600 also includes one or more output devices 610 coupled to the electronic circuitry 902, where the output devices may be a video display, audio output such as a speaker, a printer, and so one depending on the specific type of electronic system. One or more data storage devices 612 may also be coupled to the electronic circuitry 602 to store data or retrieve data from external storage media (not shown). Examples of typical storage devices 612 include solid state drives (SSDs), FLASH memories, hard and floppy disks, tape cassettes, compact disk read-only memories (CD-ROMs), compact disk read-write (CD-RW) memories, and digital video disks (DVDs), Blu-Ray disks, magnetic tape, and so on. Furthermore, the electronic circuitry 602 may be a system-on-a-chip (SoC) with all the integrated circuits 604, 606 being formed on the same die, or these integrated circuits may be formed on separate dies in other embodiments.

One skilled in the art will understood that even though various embodiments and advantages of the present disclosure have been set forth in the foregoing description, the above disclosure is illustrative only, and changes may be made in detail, and yet remain within the broad principles of the present disclosure. For example, some or all of the components described above may in other embodiments be implemented using different technologies, such as bipolar junction, gallium arsenide, thin film, or organic field effect transistors, or a combination of these technologies and the MOS technology of the above-described embodiments. Therefore, the subject matter covered by the present disclosure is to be limited only by the following claims or other claims subsequently submitted but based on the present disclosure.

1. A level shifting circuit, comprising:
a first inverter including a pair of transistors of opposite conductivity type, the first inverter adapted to receive an input signal in a first voltage domain and further including at least one additional transistor driven by a voltage in a second voltage domain; and
a second inverter is coupled in series with the first inverter and operable to generate an output signal in the second voltage domain, the second inverter including a pair of transistors of opposite conductivity type, and further including at least one additional transistor driven by a voltage in the first voltage domain, the additional transistors being operable to approximately equalize the fall times of signals generated by the first and second inverters.

2-20. (canceled)
